(19) United States
(12) Patent Application Publication
(10) Pub. No.: US 2011/0089448 A1
(43) Pub. Date: Apr. 21, 2011

(54) Single Encapsulant For A Plurality Of Light Sources

(75) Inventors: Lig Yi Yong, Simpang Ampat (MY); Kum Soon Wong, Kuala Lumpur (MY); Kean Loo Keh, Gelugor (MY)

(73) Assignee: AVAGO TECHNOLOGIES ECBU IP (SINGAPORE) PTE. LTD., Singapore (SG)

(21) Appl. No.: 12/582,692

(22) Filed: Oct. 20, 2009

(51) Int. Cl. H01L 33/58; H01J 1/62; H01L 33/52

(52) U.S. Cl. 257/98; 313/500; 313/512; 257/E33.059

(57) ABSTRACT

In an embodiment, the invention provides a light source comprising a plurality of light-emitting semiconductor chips, a plurality of electrical leads and an encapsulant. The plurality of electrical leads is connected to the plurality of light-emitting semiconductor chips. The encapsulant completely encases the plurality of semiconductor chips. The encapsulant partially encases the plurality of electrical leads.

### BACKGROUND

In the area of digital imaging, a pixel (or picture element) is usually the smallest item of information in an image. Pixels are normally arranged in a two-dimensional gird and are often represented using dots or squares. Each pixel is a sample of an original image, where more samples typically provide more accurate representations of the original image. The intensity of each pixel is usually variable. In color systems, such as flat-panel televisions, each pixel has typically three or four components. A three component pixel may have, for example, red, green and blue components. A four component pixel may have, for example, cyan, magenta, yellow and black components.

Color components are usually LEDs (Light Emitting Diodes). LEDs are based on a semiconductor diode chips. When a semiconductor diode chip is forward biased, electrons recombine with holes and energy is released in the form of light. This effect is called electroluminescence. The color of the light is determined by the energy gap of the semiconductor diode chip. The semiconductor diode chip is usually small in area, often less than 1 mm². A package that contains a semiconductor diode chip is usually larger than the semiconductor diode chip. For example, the diameter of a discrete packaged LED may be 4 or 5 mm.

A FCD (full color display) board typically uses discrete color LEDs to form a pixel. A FCD board is usually a very large video screen such as those used in baseball stadiums, arena events, music events and large format advertising on the side of buildings. Because discrete LEDs are often used to form a pixel, the pixel-to-pixel pitch size may limit the number of pixels used in a FCD board. Having more pixels on a FCD board usually increases the contrast and resolution of the FCD board. Reducing the size of a pixel makes it possible to include more pixels on a FCD board. Combining individual LED chips into a single package reduces the size of the pixel.

### BRIEF DESCRIPTION OF THE DRAWINGS

FIG. 1 is a sectional view of a discrete LED (Prior Art).

FIG. 2 is a sectional view of a discrete LED in a mold (Prior Art).

FIG. 3 is a top view of a mold (Prior Art).

FIG. 4 is a diagram of a pixel containing three discrete LEDs (Prior Art).

FIG. 5 is an isometric view of a pixel containing three discrete LEDs (Prior Art).

FIG. 6 is a front view of a pixel containing three LED chips in a single encapsulant in accordance with an embodiment of the invention.

FIG. 7 is a side view of a pixel containing three LED chips in a single encapsulant in accordance with an embodiment of the invention.

FIG. 8 is a top view of a mold for forming three LED chips into a single encapsulant in accordance with an embodiment of the invention.

FIG. 9 is a top view of a pixel containing three LED chips in a single encapsulant in accordance with an embodiment of the invention.

FIG. 10 is a front view of a pixel containing three LED chips in a single encapsulant in accordance with an embodiment of the invention.

FIG. 11 is a side view of a pixel containing three LED chips in a single encapsulant in accordance with an embodiment of the invention.

FIG. 12 is a top view of a mold for forming three LED chips into a single encapsulant in accordance with an embodiment of the invention.

### DETAILED DESCRIPTION

The drawings and description, in general, disclose a light source containing a plurality of light-emitting semiconductor chips, electrical leads for each light-emitting semiconductor chip and a discrete encapsulant. The discrete encapsulant completely encases the plurality of light-emitting semiconductor chips and partially encases the electrical leads. Because several light-emitting semiconductor chips may be included in a single discrete encapsulant, a pixel may have a smaller size than a pixel using several individually packaged light-emitting semiconductor chips. As result, a video display may have more pixels which results in better contrast and resolution.

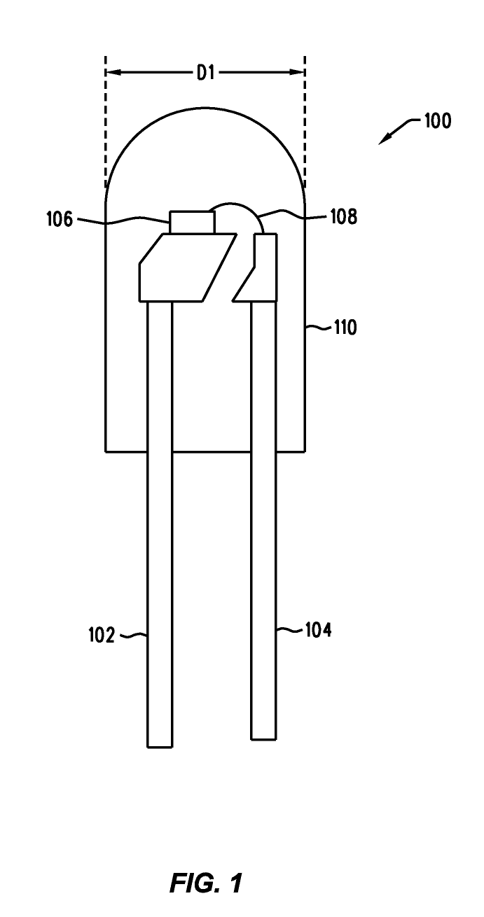

FIG. 1 is a sectional view of a discrete LED 100 (Prior Art). A first lead frame 102 is electrically connected to a LED chip 106. A wire bond 108 is electrically connected to the LED chip 106 and a second lead frame 104. An encapsulant 110 completely encases the LED chip 106 and the wirebond 108. The encapsulant 110 partially encases lead frames 102 and 104. A voltage may be applied to lead frames 102 and 104 to cause the LED chip to emit light. In this example a single LED chip 106 is encased by the encapsulant 110. In this example, the encapsulant has cylindrical shape with a diameter D1.

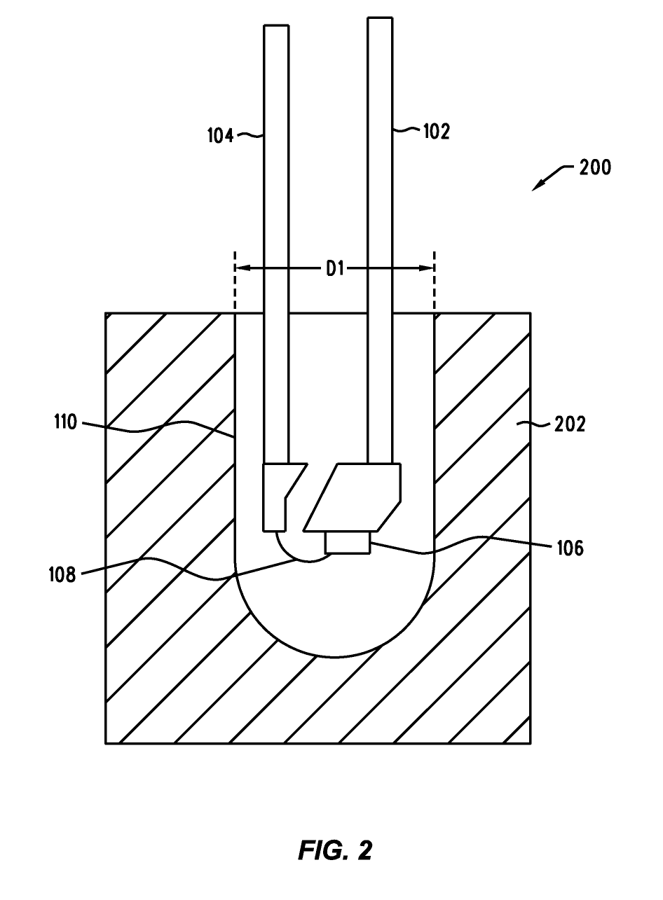

FIG. 2 is a sectional view of a discrete LED 100 in a mold 202 (Prior Art). In this example, a discrete LED 100 is formed by injecting epoxy into the mold 202 to form an encapsulant 110 around LED chip 106 and wirebond 108. The epoxy also partially covers lead frames 102 and 104. After the epoxy cures, the discrete LED is removed from the mold. In this example only one LED chip 106 is included in the encapsulant 110.

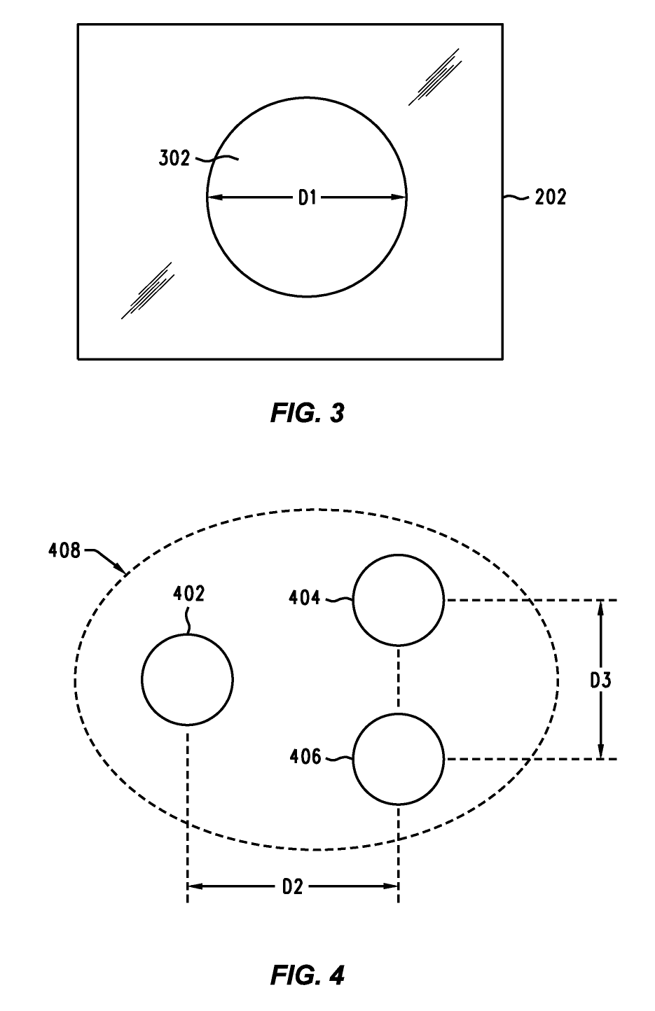

FIG. 3 is a top view of a mold 202 (Prior Art). In this view of a mold 202, a cavity 302 is shown. The cavity has a diameter D1. A discrete LED 100 may be formed in this mold 202 by injecting epoxy into the cavity 302 such that the epoxy completely encases the LED chip 106 and the wire bond 108. The lead frames 102 and 104 are partially encased by the epoxy.

FIG. 4 is a diagram of a pixel 408 containing three discrete LEDs (Prior Art). In this example a pixel 408 is formed by positioning three discrete LEDs 402, 404 and 406 as close to each other as physically possible. The size of the pixel may be defined by the distances D2 and D3. Because there are three discrete LEDs 402, 404 and 406, the minimum size of the pixel may be limited.

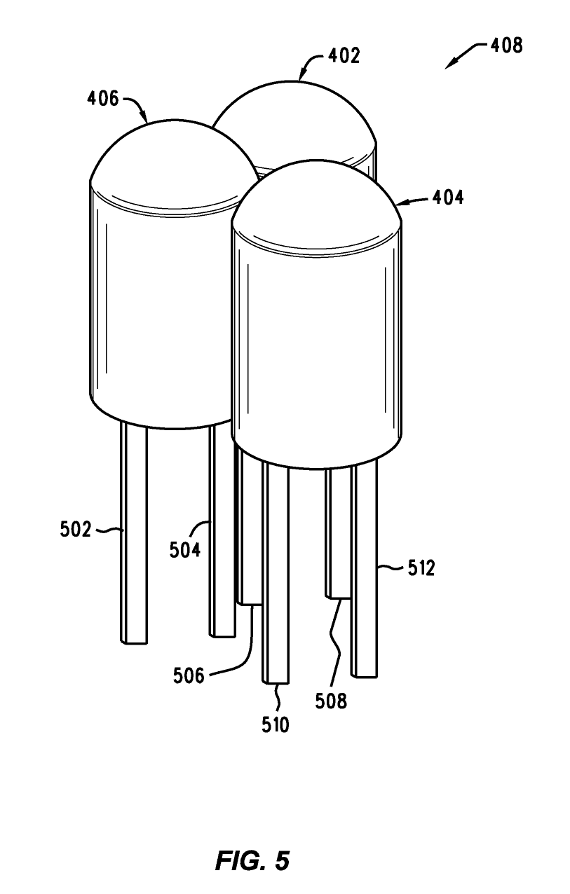

FIG. 5 is an isometric view of a pixel 408 containing three discrete LEDs 402, 404 and 406 (Prior Art). In this example the pixel 408 is formed by positioning three discrete LEDs 402, 404 and 406 as close to each other as physically possible. In this example, a first voltage may be applied to lead frames 502 and 504. A second voltage may be applied to lead frames 506 and 508. A third voltage may be applied to lead frames 510 and 512.

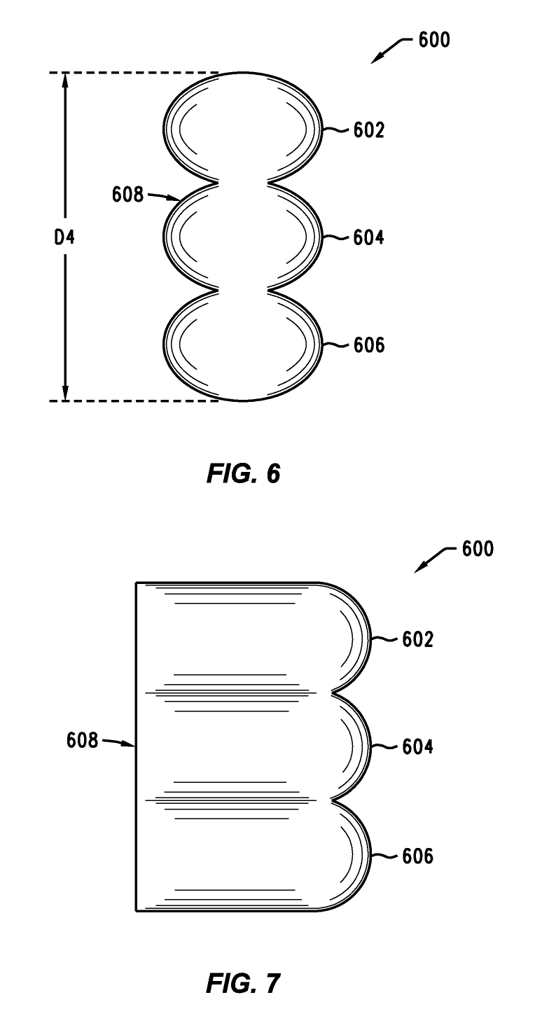

FIG. 6 is a front view of a pixel 600 containing three LED chips in a single encapsulant 608 in accordance with an embodiment of the invention. In this example, three LED chips (not shown) are included in a single discrete encapsulant 608. However, other light-emitting semiconductor chips may be used as well. In this embodiment, a lens, 602 604 and 606, is formed in epoxy for each of the three LED chips. However, lenses may be added after the encapsulant 608 is formed. Electrical leads are not shown in this example however electrical lead such as SOJ leads, J-leads, reverse gull wing leads and straight cut leads may be used in embodiments of this invention. One or more wire bonds may be used to connect the light-emitting semiconductor chips to lead frames for example.

Three light-emitting semiconductor chips are used in this example of the invention. However, any number of light-emitting semiconductor chips may be used. Electromagnetic radiation emitted from the light-emitting semiconductor chips includes but is not limited to visible light, ultra-violet light and infra-red light. In this example, a first LED chip emits blue light, a second LED chip emits green light and a third LED chip emits red light. The type of light-emitting semiconductor chips used includes but is not limited to LEDs and lasers. The material used to make the encapsulant includes but it not limited to epoxy, silicon and glass. Diffussants and phosphors may also be included in the encapsulant.

In this embodiment, the center of the lenses 602, 604 and 606 approximately intersect the y axis. However, other configurations of the lenses and LED chips are possible as will be explained later. Because a single discrete encapsulant 608 is used to encase three LEDs in this example, a smaller pixel size than a pixel size that uses three discrete LEDs may be obtained.

FIG. 7 is a side view of a pixel 600 containing three LED chips in a single discrete encapsulant 608 in accordance with an embodiment of the invention. structure. In this example, lenses 602, 604 and 606 are formed on the single discrete encapsulant. In this example, the LED chips are not shown.

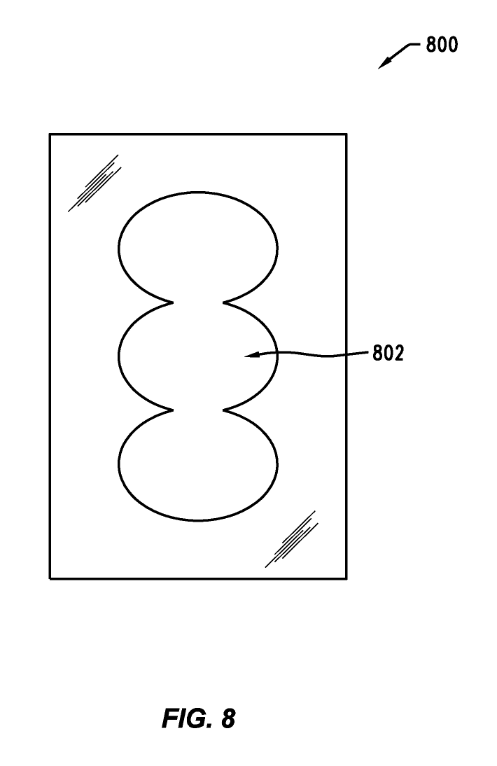

FIG. 8 is a top view of a mold 800 in accordance with an embodiment of the invention. In this view of a mold 800, a cavity 802 is shown. A encapsulant with three LED chips (not shown) may be formed in this mold by injecting epoxy into the cavity 802 such that the epoxy completely encases the LED chips and any wire bonds needed. Electrical leads are partially encased by the epoxy. The cavity 802 formed by the mold 800 may be filled, for example, using injection molding, transfer molding, and compression molding.

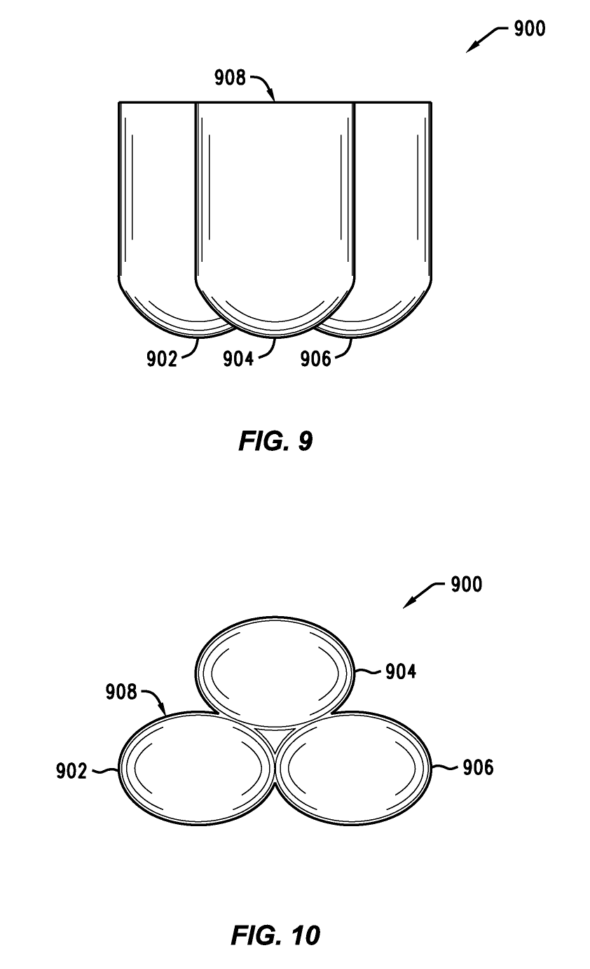

FIG. 9 is a front view of a pixel 900 containing three LED chips in a single encapsulant 908 in accordance with an embodiment of the invention. In this example, three LED chips (not shown) are included in a single discrete encapsulant 908. However, other light-emitting semiconductor chips may be used as well. In this embodiment, a lens, 902 904 and 906, is formed in epoxy for each of the three LED chips. However, lenses may be added after the encapsulant 908 is formed. Electrical leads are not shown in this example however electrical lead such as SOJ leads, J-leads, reverse gull wing leads and straight cut leads may be used in embodiments of this invention. One or more wire bonds may be used to connect the light-emitting semiconductor chips to lead frames for example.

Three light-emitting semiconductor chips are used in this example of the invention. However, any number of light-emitting semiconductor chips may be used. Electromagnetic radiation emitted from the light-emitting semiconductor chips includes but is not limited to visible light, ultra-violet light and infra-red light. In this example, a first LED chip emits blue light, a second LED chip emits green light and a third LED chip emits red light. The type of light-emitting semiconductor chips used includes but is not limited to LEDs and lasers. The material used to make the encapsulant 908 includes but is not limited to epoxy, silicon and glass. Diffussants and phosphors may also be included in the encapsulant 908.

In this embodiment, the center of the lenses 902 and 906 approximately intersect the x axis. The center of lens 904 is located above lenses 902 and 906 and the center of lens 904 is equidistant from the centers of lenses 902 and 906. However, other configurations of the lenses and LED chips are anticipated. Because a single discrete encapsulant 908 is used to encase three LEDs in this example, a smaller pixel size than a pixel size that uses three discrete LEDs may be obtained.

FIG. 10 is a front view of a pixel 900 containing three LED chips in a single discrete encapsulant 908 in accordance with an embodiment of the invention. In this example, lenses 902, 904 and 906 are formed on the single discrete encapsulant 908. In this example, the LED chips are not shown.

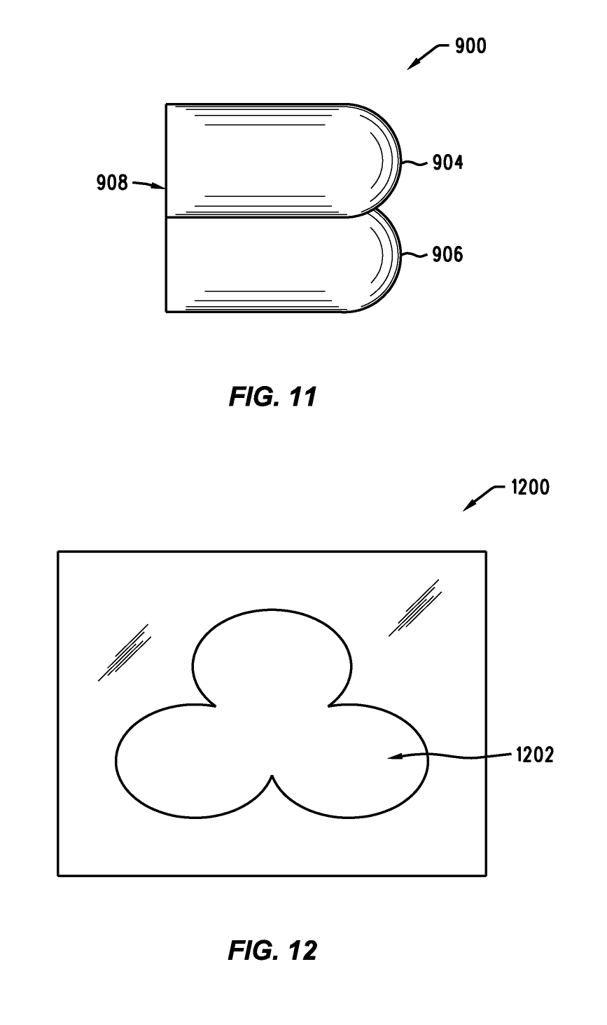

FIG. 11 is a side view of a pixel 900 containing three LED chips in a single discrete encapsulant 908 in accordance with an embodiment of the invention. In this example, lenses 902, 904 and 906 are formed on the single discrete encapsulant 908. In this example, the LED chips are not shown.

FIG. 12 is atop view of a mold 1200 in accordance with an embodiment of the invention. In this view of a mold 1200, a cavity 1202 is shown. A encapsulant with three LED chips (not shown) may be formed in this mold by injecting epoxy into the cavity 1202 such that the epoxy completely encases the LED chips and any wire bonds needed. Electrical leads are partially encased by the epoxy. The cavity 1202 formed by the mold 1200 may be filled, for example, using injection molding, transfer molding, and compression molding.

The foregoing description has been presented for purposes of illustration and description. It is not intended to be exhaustive or to limit the invention to the precise form disclosed, and other modifications and variations may be possible in light of the above teachings. The exemplary embodiments were chosen and described in order to best explain the applicable principles and their practical application to thereby enable others skilled in the art to best utilize various embodiments and various modifications as are suited to the particular use contemplated. It is intended that the appended claims be construed to include other alternative embodiments except insofar as limited by the prior art.

What is claimed is:

1. A light source comprising:
a plurality of light-emitting semiconductor chips;
a plurality of electrical leads;
an encapsulant;
wherein each of the plurality of light-emitting semiconductor chips is electrically connected to first electrical leads from the plurality of electrical leads;
wherein each of the plurality of light-emitting semiconductor chips is electrically connected to second electrical leads from the plurality of electrical leads;
wherein the encapsulant completely encases the plurality of semiconductor chips;
where the encapsultant partially encases the plurality of electrical leads.

2. The light source of claim 1 wherein the encapsulant forms a lens for each light-emitting semiconductor chip from the plurality of light-emitting semiconductor chips.

3. The light source of claim 1 wherein a lens is attached to the encapsulant for each light-emitting semiconductor chip from the plurality of semiconductor chips.

4. The light source of claim 1 wherein the plurality of electrical leads are selected from a group of electrical leads consisting of J leads, SOJ leads, gull wing leads, reverse gull wing leads and straight cut leads.

5. The light source of claim 1 wherein the first and second electrical leads are connected to the plurality of light-emitting semiconductor chips by wire bonds.

6. The light source of claim 1 wherein the second electrical leads from the plurality of electrical leads are connected to the plurality of light-emitting semiconductor chips by wire bonds.

7. The light source of claim 1 wherein the encapsulant comprises a material selected from a group consisting of epoxy, silicone and a glass material.

8. The light source of claim 1 wherein the encapsulant further comprises material selected from a group consisting of diffussants and phosphors.

9. The light source of claim 1 wherein the plurality of light-emitting semiconductor chips is selected from a group consisting of an LED and a laser.

10. The light source of claim 1 wherein electromagnetic radiation emitted from the plurality of light-emitting semiconductor chips includes visible light, ultra-violet light and infra-red light.

11. A pixel element comprising:
a first LED chip having a first and second electrical lead;
a second LED chip having a first and second electrical lead;
a third LED having a first and second electrical connection lead;
an encapsulant;
wherein the encapsulant completely encases the first, second and third LED chips;
wherein the encapsultant partially encases the first and second leads of the first LED chips, the first and second leads of the second LED chip and the first and second leads of the third LED chip.

12. The pixel element in claim 11 wherein the first LED chip emits green light, the second LED chip emits blue light, and the third LED chip emits red light.

13. The pixel element in claim 11 wherein the encapsulant forms a first lens for the first LED chip, a second lens for the second LED chip and a third lens for the third LED chip.

14. The pixel element in claim 13 wherein a center of the first lens, a center for the second lens and a center for the third approximately intersect an y-axis.

15. The pixel element in claim 13 wherein a center of the first lens and a center for the second lens approximately intersect an x-axis;
wherein a center of the third lens is located above the x-axis and is approximately equidistant from the center of the first lens and the center of the second lens.

16. The light source of claim 11 wherein the electrical leads are selected from a group of electrical leads consisting of J leads, SOJ leads, gull wing leads, reverse gull wing leads and straight cut leads.

17. A pixel element comprising:
a first LED chip having a first and second electrical lead;
a second LED chip having a first and second electrical lead;
a third LED having a first and second electrical connection lead;
a fourth LED having a first and second electrical connection lead;
an encapsulant;
wherein the encapsulant completely encases the first, second, third and fourth LED chips;
wherein the encapsultant partially encases the first and second leads of the first LED chip, the first and second leads of the second LED chip, the first and second leads of the third LED chip and the first and second leads of the fourth lead chip.

18. The pixel element in claim 17 wherein the first LED chip emits green light, the second LED chip emits blue light, the third LED chip emits red light and the fourth LED chip emits amber light.

19. The pixel element in claim 17 wherein the encapsulant forms a first lens for the first LED chip, a second lens for the second LED chip, a third lens for the third LED chip and fourth lens for the fourth LED chip.

20. The pixel element in claim 19 wherein a center of the first lens and a center for the second lens approximately intersect an x-axis;
wherein a center for a third lens and a center for a fourth lens approximately intersect a y-axis;
wherein the center of the first lens, the center of the second lens, the center of the third lens and the center of the fourth lens are equidistant from the intersection of the x axis and y axis.
